(19) United States
(12) Patent Application Publication
(10) Pub. No.: US 2012/0024223 A1
(43) Pub. Date: Feb. 2, 2012

(54) Thin films and methods of making them using cyclohexasilane

(75) Inventors: Robert Torres, JR., Parker, CO (US); Terry Arthur Francis, Schenectady, NY (US); Satoshi Hasaka, Tokyo (JP); Paul David Brabant, East Greenbush, NY (US)

(73) Assignee: Matheson Tri-Gas, Inc., Basking Ridge, NJ (US)

(21) Appl. No.: 13/135,033

(22) Filed: Jun. 23, 2011

Related U.S. Application Data
(60) Provisional application No. 61/398,980, filed on Jul. 2, 2010.
(60) Provisional application No. 61/402,191, filed on Aug. 24, 2010.

(51) Int. Cl. C30B 25/14; C30B 25/12

(52) U.S. Cl. 117/104; 118/728

(57) ABSTRACT

Cyclohexasilane is used in chemical vapor deposition methods to deposit epitaxial silicon-containing films over substrates. Such methods are useful in semiconductor manufacturing to provide a variety of advantages, including uniform deposition over heterogeneous surfaces, high deposition rates, and higher manufacturing productivity. Furthermore, the crystalline Si may be in situ doped to contain relatively high levels of substitutional carbon by carrying out the deposition at a relatively high flow rate using cyclohexasilane as a silicon source and a carbon-containing gas such as dodecalmethylcyclohexasilane or tetramethyldisilane under modified CVD conditions.

### CROSS REFERENCE TO OTHER APPLICATIONS

This application claims benefit of priority to two provisional U.S. Application Nos. 61/398,980, filed Jul. 2, 2010, and 61/402,191, filed Aug. 24, 2010, the disclosures of which are fully incorporated herein by reference.

### BACKGROUND OF THE INVENTION

1. Field of the Invention

The present invention relates generally to selective epitaxial deposition of silicon-containing materials and more particularly to the use of cyclohexasilane, C₆H₁₂, in chemical vapor deposition processes for the deposition of thin silicon-containing materials on various substrates.

2. Description of the State of the Art

The ability to produce thin films is becoming more important as circuit dimensions shrink and the resulting devices become more compact. Chemical vapor deposition (CVD) is a chemical process used to produce high-purity, high-performance solid materials. The process is often used in the semiconductor industry to produce thin films. In a typical CVD process, the wafer (substrate) is exposed to one or more volatile precursors, which react and/or decompose on the substrate surface to produce the desired deposit. Frequently, volatile by-products are also produced, which are removed by gas flow through the reaction chamber.

A number of forms of CVD are in wide use and are frequently referenced in the literature. These processes differ in the means by which chemical reactions are initiated (e.g., activation process) and process conditions. The following are but a few examples of CVD as classified by operating pressure:
Low-pressure CVD (LPCVD)—CVD processes at subatmospheric pressures (10⁻³ Torr base pressure/100 mTorr-1 Torr operating pressure).
Ultrahigh vacuum CVD (UHVCVD)—CVD processes at a very low pressure, typically 10⁻⁹ Torr base/10⁻⁵ to 50 mTorr operating pressure.
Reduced-Pressure CVD (RPCVD)—CVD process at 10⁻³ Torr base pressure/10 Torr to ATM operating pressure.
Very Low Pressure CVD (VLPCVD)—CVD process at 10⁻⁷ Torr base/10 mTorr to 50 mTorr operating pressure.

The semiconductor manufacturing industry often uses silane (SiH₄) to produce such thin films; however, the deposition of very thin (e.g., about 150 Å or less) silicon-containing films using silane is very challenging, particularly over large area substrates as film uniformity is affected by nucleation phenomena.

Nucleation is not completely understood, but silane deposition has been observed to occur by a process in which a number of separate silicon islands initially form on the surface of the substrate. As the deposition proceeds, these islands tend to grow until they contact one another, eventually forming a continuous silicon film. At this point the silicon film typically has a rough surface with peaks that correspond to the initial nucleation sites and valleys that correspond to the contact areas. The surface roughness is particularly evident when depositing layers, and particularly doped layers, over dielectric surfaces such as silicon oxide or silicon nitride. As deposition proceeds further and the film thickens, thickness uniformity increases by an averaging-out process similar to that described above.

Generally, a selective epitaxial process involves a deposition reaction and an etch reaction. The deposition and etch reactions occur simultaneously with relatively different reaction rates to an epitaxial layer and to a polycrystalline layer. During the deposition process, the epitaxial layer is formed on a monocrystalline surface while a polycrystalline layer is deposited on at least a second layer, such as an existing polycrystalline layer and/or an amorphous layer. However, the deposited polycrystalline layer is generally etched at a faster rate than the epitaxial layer. Therefore, by changing the concentration of an etchant gas, the net selective process results in deposition of epitaxial material and limited, or no, deposition of polycrystalline material. For example, a selective epitaxial process may result in the formation of an epilayer of silicon-containing material on a monocrystalline silicon surface while no deposition is left on the spacer.

However, current selective epitaxial processes have some drawbacks. In order to maintain selectivity during present epitaxial processes, chemical concentrations of the precursors, as well as reaction temperatures must be regulated and adjusted throughout the deposition process. If not enough silicon precursor is administered, then the etching reaction may dominate and the overall process is slowed down. If not enough etchant precursor is administered, then the deposition reaction may dominate reducing the selectivity to form monocrystalline and polycrystalline materials across the substrate surface. Also, current selective epitaxial processes usually require a high reaction temperature, such as about 800° C., 1,000° C. or higher. Such high temperatures are not desirable during a fabrication process due to thermal budget considerations and possible uncontrolled nitridation reactions to the substrate surface.

Film deposition methods that utilize a Si-containing precursor, preferably trisilane (H₃SiSiH₂SiH₃), have been disclosed in U.S. Pat. No. 6,962,859, which is hereby incorporated herein by reference in its entirely, that are much less sensitive to nucleation phenomena across the surface of the substrate. Unfortunately, commercially available trisilane is expensive, it often carries contaminant levels that are unsatisfactory and its decomposition rate is very fast, decomposing at temperatures between 400-500° C. and pressures between 2000-6000 psi.

The performance of semiconductors devices may be further enhanced by increasing circuit performance. The amount of current that flows through the channel of a metal oxide semiconductor (MOS) transistor is directly proportional to a mobility of carriers in the channel, and the use of high mobility MOS transistors enables more current to flow and consequently faster circuit performance. For example, mobility of the carriers in the channel of a MOS transistor can be increased by producing a mechanical stress, i.e., strain, in the channel.

A number of approaches for inducing strain in Si- and Ge-containing materials have focused on exploiting the differences in the lattice constants between various crystalline materials. In one approach, thin layers of a particular crystalline material are deposited onto a different crystalline material in such a way that the deposited layer adopts the lattice constant of the underlying single crystal material.

Strain may also be introduced into single crystalline Si-containing materials by replacing Si in the lattice structure with a dopant, commonly referred to as substitutional doping. For example, substitution of germanium atoms for some of the silicon atoms in the lattice structure of single crystalline silicon produces a compressive strain in the resulting substitutionally doped single crystalline silicon material because the germanium atoms are larger than the silicon atoms that they replace. Alternatively, a tensile strain may be introduced into single crystalline silicon by substitutional doping with carbon, because carbon atoms are smaller than the silicon atoms that they replace. See, e.g., Judy L. Hoyt, “Substitutional Carbon Incorporation and Electronic Characterization of Si_{1-y}C_{y}/Si and Si_{1-x-y}GeₓC_{y}/Si Heterojunctions,” Chapter 3 in “Silicon-Germanium Carbon Alloy,” Taylor and Francis, N.Y., pp. 59-89, 2002, the disclosure of which is incorporated herein by reference.

In situ doping is often preferred over ex situ doping followed by annealing to incorporate the dopant into the lattice structure because the annealing may undesirably consume thermal budget. However, in practice in situ substitutional carbon doping is complicated by the tendency for the dopant to incorporate non-substitutionally during deposition, e.g., interstitially in domains or clusters within the silicon, rather than by substituting for silicon atoms in the lattice structure. See, e.g., the aforementioned article by Hoyt. Non-substitutional doping also complicates substitutional doping using other material systems, e.g., carbon doping of SiGe, doping of Si and SiGe with electrically active dopants, etc. As illustrated in FIG. 3.10 at page 73 of the aforementioned article by Hoyt, prior deposition methods have been used to make crystalline silicon having an in situ doped substitutional carbon content of up to 2.3 atomic %, which corresponds to a lattice spacing of over 5.4 Å and a tensile stress of less than 1.0 GPa. However, prior deposition methods are not known to have been successful for depositing single crystal silicon having an in situ doped substitutional carbon content of greater than 2.3 atomic %.

In addition, the elemental composition of doped thin films is often not homogeneous in the cross-film and/or through-film directions because of differences in relative incorporation rates of the dopant elements. The resulting films do not exhibit uniform elemental concentrations and, therefore, do not exhibit uniform film physical properties across the surface and/or through the thickness of the film.

The ability to economically deposit very thin, smooth Si-containing films would satisfy a long-felt need and represent a significant advance in the art of semiconductor manufacturing, particularly for making future generations of microelectronic devices having ever-smaller circuit dimensions. To that end, the use of silicon-precursors having high purity levels that are commercially available at a very reasonable price is desirable.

Additionally, there is a need to have a process for selectively and epitaxially depositing silicon and silicon-containing materials while accomplishing in situ substitutional doping of Si-containing materials. Desirably, such improved methods would be capable of achieving commercially significant levels of substitutional doping without unduly sacrificing deposition speed, selectivity, and/or the quality (e.g., crystal quality) of the deposited materials. Furthermore, the process should be versatile to form silicon-containing materials with varied elemental concentrations while having a fast deposition rate and maintaining a process temperature in the range of about 250° C.-550° C., and preferably about 500° C.-525° C. while maintaining a pressure of less than 200 Torr.

### SUMMARY OF THE INVENTION

It has been discovered that cyclohexasilane, like trisilane, can be used as a silicon precursor to deposit very thin, smooth Si-containing films over large area substrates. In accordance with one aspect of the invention, a method for depositing a thin film is provided, comprising: introducing a gas comprising cyclohexasilane to a chamber, wherein the chamber contains a substrate having a substrate surface; establishing cyclohexasilane chemical vapor deposition and decomposition conditions in the chamber; and depositing a Si-containing film onto the substrate surface.

In accordance with another aspect of the invention, a deposition method is provided, comprising: providing a substrate disposed within a chamber, wherein the substrate comprises a first surface having a first surface morphology and a second surface having a second surface morphology different from the first surface morphology; introducing cyclohexasilane to the chamber under chemical vapor deposition conditions; initiating decomposition of said cyclohexasilane; and depositing a Si-containing film onto the substrate over both of the first surface and the second surface.

In accordance with another aspect of the invention, a high-rate deposition method is provided, comprising: delivering cyclohexasilane to a mixed substrate surface under chemical vapor deposition conditions, at a delivery rate of at least about 0.001 milligrams per minute per square centimeter of the mixed substrate surface, and depositing a silicon-containing material onto the mixed substrate surface at a rate of about 10 Å per minute or greater.

In another preferred embodiment, deposition and/or growth methods have now been developed that utilize cyclohexasilane and a carbon source to deposit carbon-doped Si-containing films using a modified chemical vapor deposition and/or growth system (reduced pressure chemical CVD) which operates in the range of 10 mTorr to 200 Torr. Such deposition and/or growth methods are capable of producing a variety of Si-containing single crystal films that are substitutionally doped with carbon to various levels, including levels that are significantly higher than those achieved using prior methods. For example, preferred deposition and/or growth methods using cyclohexasilane as a silicon source can be used to deposit a variety of carbon-doped single crystal Si films having a range of substitutional carbon levels, including levels of greater than 1.8 atomic % while simultaneously maintaining a constant reaction temperature throughout the process.

Another embodiment provides a method for depositing an epitaxial silicon film, comprising: providing a substrate disposed within a chamber; initiating decomposition of said cyclohexasilane; and exposing the substrate to cyclohexasilane under reduced pressure chemical vapor deposition and/or growth conditions and depositing a single silicon film onto the substrate at a temperature of less than about 550° C. and a pressure of less than about 200 Torr.

Another embodiment provides a method for depositing an epitaxial silicon film, comprising: providing a substrate disposed within a chamber; introducing cyclohexasilane and a carbon source to the chamber under reduced pressure CVD conditions and depositing a single crystalline silicon film onto the substrate at a temperature of less than about 550° C. and a pressure of less than about 200 Torr thereby producing a single crystalline silicon film comprising at least 1.8 atomic % substitutional carbon, as determined by x-ray diffraction.

Another embodiment provides an integrated circuit comprising a first single crystalline Si-containing region and a second single crystalline Si-containing region, at least one of the first single crystalline Si-containing region and the second single crystalline Si-containing region comprising an amount of substitutional carbon effective to exert a tensile stress on a third single crystalline Si-containing region positioned between the first single crystalline Si-containing region and the second single crystalline Si-containing region, the third single crystalline Si-containing region exhibiting an increase in carrier mobility of at least about 10% as compared to a comparable unstressed region.

In another aspect of the invention, a modified low pressure-chemical vapor deposition and/or growth system is disclosed for forming an epitaxial film on a substrate, comprising a deposition and/or growth chamber having chamber dimensions and opposite ends; a decomposition chamber is operatively disposed between the cyclohexasilane source and the chamber thus allowing the initiation of cyclohexasilane decomposition prior to entry into the chamber; a gas inlet adjacent the other of the ends of the chamber for introducing decomposed cyclohexasilane into the chamber; and a substrate support means for supporting the substrates within the chamber.

In another aspect of the invention, a modified low pressure-chemical vapor deposition and/or growth system is disclosed for forming an epitaxial film on a substrate, comprising a deposition and/or growth chamber having chamber dimensions and opposite ends; a high-speed pump means connected to one of the ends of the chamber and operative to maintain the deposition and/or growth pressure in the chamber at or below 200 Torr; a gas inlet adjacent the other of the ends of the chamber for introducing gas into the chamber so that the gas flows generally in a direction from the gas inlet to the pump means; substrate support means for supporting the substrates within the chamber; and said high speed pump is capable of flowing a carrier gas into said chamber at concentrations so high that any contaminants, such as but not limited to oxygen, water, carbon monoxide, carbon dioxide, siloxanes, disiloxanes, and higher siloxanes present are diluted out.

The foregoing paragraphs have been provided by way of general introduction, and are not intended to limit the scope of the following claims. The presently preferred embodiments, together with further advantages, will be best understood by reference to the following detailed description taken in conjunction with the accompanying drawings.

### BRIEF DESCRIPTION OF THE DRAWINGS

The accompanying drawings, which are incorporated in and form a part of the specifications, illustrate the preferred embodiments of the present invention, and together with the description serve to explain the principles of the invention.

In the Drawings:

FIG. 1 is a schematic view of a reactor set up for a system employing cyclohexasilane and a carrier gas for selectively depositing silicon-containing films in accordance with the present invention.

FIG. 2 is a schematic view of a reactor for selectively depositing silicon-containing films having a degradation chamber positioned between the bubbler containing cyclohexasilane and the reaction chamber in accordance with the present invention.

FIG. 3 is a schematic view of a reactor set up for a system having a high speed pump employing cyclohexasilane, a carbon source, an etchant gas, and a carrier gas for selectively depositing silicon-containing films in accordance with the present invention.

FIG. 4 shows a schematic illustration of a device containing selectively and epitaxially deposited silicon-containing layers within a MOSFET.

### DETAILED DESCRIPTION OF THE PRESENT INVENTION

Film deposition methods that utilize cyclohexasilane (C₆H₁₂), have now been discovered that are much less sensitive to temperature variations across the surface of the substrate, magnitudes more economical than using trisilane and are capable of high substitutional carbon values. It has been discovered that cyclohexasilane, like other silicon sources, such as but not limited to trisilane, tetrasilane, disilane, pentasilane, can be used as a silicon precursor to deposit very thin, smooth Si-containing films over large area substrates. In preferred embodiments, these methods are also much less sensitive to nucleation phenomena. Practice of the deposition methods described herein provides numerous advantages. For example, the methods described herein enable the production of novel epitaxial Si-containing films that are uniformly thin, as well as doped epitaxial Si-containing films in which the dopant is uniformly distributed throughout the film, preferably in both the across-film and through-film directions and may contain relatively high levels of substitutional carbon. The methods described herein also enable the production of very thin, continuous films. These advantages, in turn, enable devices to be produced in higher yields at vastly less expensive prices, and also enable the production of new devices having smaller circuit dimensions and/or higher reliability. These and other advantages are discussed below.

“Substrate,” as that term is used herein, refers either to the workpiece upon which deposition and/or growth is desired, or the surface exposed to the deposition and/or growth gas(es). For example, the substrate may be a single crystal silicon wafer, or may be a semiconductor-on-insulator (SOI) substrate, or may be an epitaxial Si, SiGe or III-V material deposited upon such wafers. Workpieces are not limited to wafers, but also include glass, plastic, or any other substrate employed in semiconductor processing.

As used herein, a “mixed substrate” is a substrate that has two or more different types of surfaces. There are various ways that surfaces can be different from each other. For example, the surfaces can be made from different elements such as copper or silicon, or from different metals, such as copper or aluminum, or from different Si-containing materials, such as silicon or silicon dioxide. Even if the materials are made from the same element, the surfaces can be different if the morphologies of the surfaces are different. The electrical properties of surfaces can also make them different from each other. In the illustrated examples, silicon-containing layers are simultaneously formed over conductive semiconductive materials and dielectrics. Examples of dielectric materials include silicon dioxide (including low dielectric constant forms such as carbon-doped and fluorine-doped oxides of silicon), silicon nitride, metal oxide and metal silicate.

The terms “epitaxial”, “epitaxially” “heteroepitaxial”, “heteroepitaxially”, “single-crystal” and similar terms are used herein to refer to the deposition and/or growth of a crystalline Si-containing material onto a crystalline substrate in such a way that the deposited layer adopts or follows the lattice constant of the substrate. Epitaxial deposition and/or growth may be heteroepitaxial when the composition of the deposited layer is different from that of the substrate. The skilled artisan will appreciate that crystallinity of a layer generally falls along a continuum from amorphous to polycrystalline to single-crystal; the skilled artisan can readily determine when a crystal structure can be considered single-crystal or epitaxial, despite low density faults. Specific examples of mixed substrates include without limitation single crystal/polycrystalline, single crystal/amorphous, epitaxial/polycrystalline, epitaxial/amorphous, single crystal/dielectric, epitaxial/dielectric, conductor/dielectric, and semiconductor/dielectric.

Even if the materials are made from the same element, the surfaces can be different if the morphologies (crystallinity) of the surfaces are different. The processes described herein are useful for depositing Si-containing films on a variety of substrates, but are particularly useful for mixed substrates having mixed surface morphologies. Such a mixed substrate comprises a first surface having a first surface morphology and a second surface having a second surface morphology. In this context, “surface morphology” refers to the crystalline structure of the substrate surface. Amorphous and crystalline are examples of different morphologies. Polycrystalline morphology is a crystalline structure that consists of a disorderly arrangement of orderly crystals and thus has an intermediate degree of order. The atoms in a polycrystalline material are ordered within each of the crystals, but the crystals themselves lack long range order with respect to one another. Single crystal morphology is a crystalline structure that has a high degree of long range order. Epitaxial films are characterized by a crystal structure and orientation that is identical to the substrate upon which they are grown, typically single crystal. The atoms in these materials are arranged in a lattice-like structure that persists over relatively long distances (on an atomic scale). Amorphous morphology is a non-crystalline structure having a low degree of order because the atoms lack a definite periodic arrangement. Other morphologies include microcrystalline and mixtures of amorphous and crystalline material.

Embodiments of the invention generally provide methods and apparatus for forming and treating a silicon-containing epitaxial layer. Specific embodiments pertain to methods and apparatus for forming and treating an epitaxial layer during the manufacture of a transistor.

Throughout the application, the terms “silicon-containing” materials, compounds, films or layers should be construed to include a composition containing at least silicon and may contain germanium, carbon, boron, arsenic, phosphorus gallium and/or aluminum. Other elements, such as metals, halogens or hydrogen may be incorporated within a silicon-containing material, compound, film or layer, usually in part per million (ppm) concentrations. Compounds or alloys of silicon-containing materials may be represented by an abbreviation, such as Si for silicon, SiGe for silicon germanium, Si:C for silicon carbon and SiGeC for silicon germanium carbon. The abbreviations do not represent chemical equations with stoichiometrical relationships, nor represent any particular reduction/oxidation state of the silicon-containing materials.

Under the CVD conditions taught herein, the delivery of cyclohexasilane to the surface of a substrate results in the formation of a Si-containing film. Preferably, delivery of decomposed cyclohexasilane to the surface whether it be mixed or patterned substrate surface is accomplished by introducing the cyclohexasilane to a suitable chamber having the substrate disposed therein. By introducing cyclohexasilane to the chamber under CVD conditions and initiating decomposition of cyclohexasilane a high quality Si-containing film can be deposited onto the surface of the substrate regardless of the various surface types. Deposition may be suitably conducted according to the various CVD methods known to those skilled in the art, but the greatest benefits are obtained when deposition is conducted according to the CVD methods taught herein. The disclosed methods may be suitably practiced by employing CVD, including plasma-enhanced chemical vapor deposition (PECVD) or thermal CVD, utilizing gaseous cyclohexasilane to deposit a Si-containing film onto a mixed substrate contained within a CVD chamber. Thermal CVD is preferred.

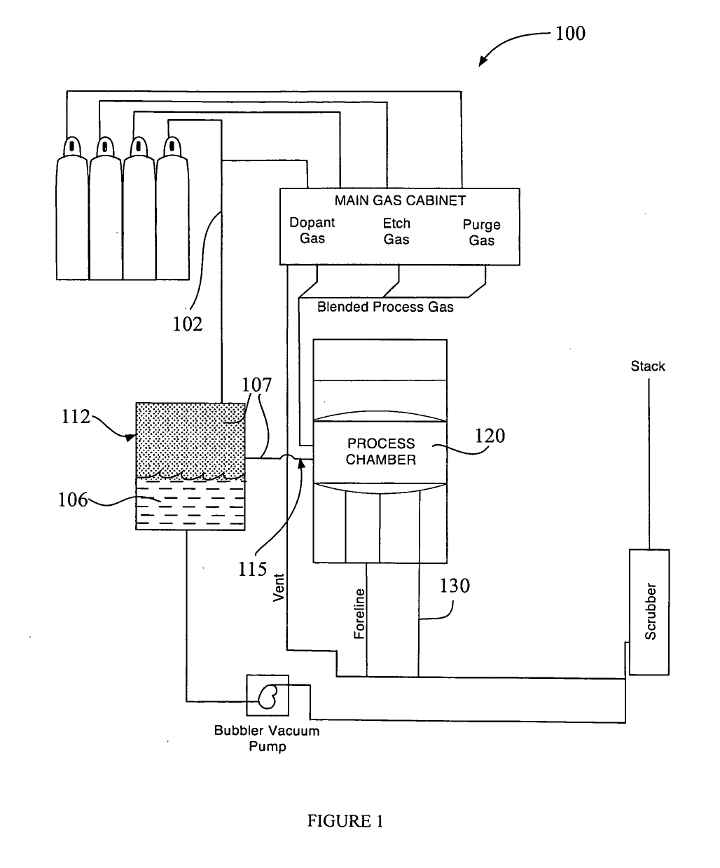

As shown in FIG. 1, cyclohexasilane 106 is preferably introduced to the chamber 120 in the form of a gas or as a component of a feed gas. The total pressure in the CVD chamber is preferably in the range of about 0.001 torr to about 1000 torr, more preferably in the range of about 0.1 torr to about 850 torr, most preferably in the range of about 1 torr to about 760 torr. The temperature of the chamber is preferably about 450° C. or greater, more preferably about 500° C. or greater, even more preferably about 550° C. or greater. Preferably, deposition takes place at a temperature of about 750° C. or less, more preferably about 725° C. or less, most preferably about 700° C. or less. The substrate can be heated by a variety of manners known in the art. Those skilled in the art can adjust these temperature ranges to take into account the realities of actual manufacturing, e.g., preservation of thermal budget, deposition rate, etc. However, it is critical that the temperature reach the point at which decomposition of cyclohexasilane is initiated. Preferred deposition temperatures thus depend on the desired application, but are typically in the range of about 400° C. to about 750° C., preferably about 425° C. to about 725° C., more preferably about 450° C. to about 700° C.

The partial pressure of cyclohexasilane is preferably in the range of about 0.0001% to about 100% of the total pressure, more preferably about 0.001% to about 50% of the total pressure. The feed gas 102 can include a gas or gases other than cyclohexasilane, such as inert carrier gases. Hydrogen is typically a preferred carrier gas due to improved hydrogen termination. However other inert carrier gases such as argon, helium, and nitrogen may also be employed. Preferably, cyclohexasilane is introduced to the chamber by way of a bubbler 112 used with a carrier gas 102 to entrain cyclohexasilane vapor 107, more preferably a temperature controlled bubbler.

A suitable manifold may be used to supply feed gas(es) to the CVD chamber. In the illustrated embodiments, the gas flow in the CVD chamber is horizontal, most preferably the chamber is a single-wafer, single pass, laminar horizontal gas flow reactor, preferably radiantly heated. Suitable reactors of this type are commercially available, and preferred models include Centura® RP-CVD (Reduced Pressure-Vacuum Chemical Vapor Deposition) manufactured by Applied Materials. While the methods described herein can also be employed in alternative reactors, such as a showerhead arrangement, benefits in increased uniformity and deposition rates are likely to be found particularly effective in the horizontal, single-pass laminar gas flow arrangement of the Centura® chambers, employing a rotating substrate, particularly with low process gas residence times. CVD may be conducted by introducing plasma products (in situ or downstream of a remote plasma generator) to the chamber, but thermal CVD is preferred.

The feed gas may also contain other materials known by those skilled in the art to be useful for doping or alloying Si-containing films, as desired. Preferably the gas further comprises one or more precursors selected from the group consisting of germanium source, carbon source, boron source, gallium source, indium source, arsenic source, phosphorous source, antimony source, nitrogen source and oxygen source. Specific examples of such sources include: silane, disilane and cyclohexasilane as silicon sources; germane, digermane and trigermane as germanium sources; NF₃, ammonia, hydrazine and atomic nitrogen as nitrogen sources; various hydrocarbons, e.g., methane, ethane, propane, etc. as carbon sources; monosilylmethane, disilylmethane, trisilylmethane, and tetrasilylmethane as sources of both carbon and silicon; N₂O and NO₂ as sources of both nitrogen and oxygen; and various dopant precursors as sources of dopants such as antimony, arsenic, boron, gallium, indium and phosphorous. Carbon sources useful to deposit silicon-containing compounds include organosilanes, cyclohexasilanes, alkyls, alkenes and alkynes of ethyl, propyl and butyl. Such carbon sources include but are not limited to carbon sources having a general formula of SiₓH_{y}(CH₃)_{z}, where x is an integer in the range of 1 to 6 and where y and z are each independently an integer in the range of 0 to 6, methylated cyclohexasilane or dodecamethylcyclohexasilane (Si₆Cl₂H₃₆) and silylalkanes such as tetramethyldisilane (TMDS), monosilylmethane, disilylmethane, trisilylmethane and tetrasilylmethane, and/or alkylsilanes such as monomethyl silane (MMS), and dimethyl silane, methylsilane (CH₃SiH₃), dimethylsilane ((CH₃)₂SiH₂), ethylsilane (CH₃CH₂SiH₃), methane (CH₄), ethylene (C₂H₄), ethyne (C₂H₂), propane (C₃H₈), propene (C₃H₆), butyne (C₄H₆), as well as others.

Incorporation of dopants into Si-containing films by CVD using cyclohexasilane is preferably accomplished by in situ doping using dopant precursors. Precursors for electrical dopants include diborane, deuterated diborane, phosphine, arsenic vapor, and arsine. Silylphosphines [(H₃Si₃)₃₋ₓPRₓ] and silylarsines [(H₃Si)₃—, AsRₓ] where x=0-2 and Rₓ=H and/or D are preferred precursors for phosphorous and arsenic dopants. SbH₃ and trimethylindium are preferred sources of antimony and indium, respectively. Such dopant precursors are useful for the preparation of preferred films as described below, preferably boron-, phosphorous-, antimony-, indium-, and arsenic-doped silicon, SiC, SiGe and SiGeC films and alloys. As used herein, “SiC”, “SiGe”, and “SiGeC” represent materials that contain the indicated elements in various proportions. For example, “SiGe” is a material that comprises silicon, germanium and, optionally, other elements, e.g., dopants. “SiC”, “SiGe”, and “SiGeC” are not chemical stoichiometric formulas per se and thus are not limited to materials that contain particular ratios of the indicated elements.

The amount of dopant precursor in the feed gas may be adjusted to provide the desired level of dopant in the Si-containing film. Typical concentrations in the feed gas can be in the range of about 1 part per billion (ppb) to about 1% by weight based on total feed gas weight, although higher or lower amounts are sometimes preferred in order to achieve the desired property in the resulting film. In the preferred Centura® series of single wafer reactors, dilute mixtures of dopant precursor in a carrier gas can be delivered to the reactor via a mass flow controller with set points ranging from about 10 to about 200 standard cubic centimeters per minute (sccm), depending on desired dopant concentration and dopant gas concentration. The dilute mixture is preferably further diluted by mixing with cyclohexasilane and any suitable carrier gas. Since typical total flow rates for deposition in the preferred Centura® series reactors often range from about 20 standard liters per minute (slm) to about 180 slm, the concentration of the dopant precursor used in such a method is small relative to total flow.

Deposition of the Si-containing films described herein is preferably conducted at a rate of about 5 Å per minute or higher, more preferably about 10 Å per minute or higher, most preferably about 20 Å per minute or higher. A preferred embodiment provides a high rate deposition method in which cyclohexasilane is delivered to the substrate surface at a delivery rate of at least about 0.001 milligram per minute per square centimeter of the substrate surface, more preferably at least about 0.003 milligram per minute per square centimeter of the substrate surface. Under CVD conditions, preferably at a deposition temperature in the range of about 450° C. to about 700° C., practice of this embodiment results in relatively fast deposition of the Si-containing material (as compared to other silicon sources), preferably at a rate of about 10 Å per minute or higher, more preferably about 25 Å per minute or higher, most preferably about 50 Å per minute or higher. Preferably, a germanium source is also delivered to the surface along with the cyclohexasilane to thereby deposit a SiGe-containing material as the Si-containing material.

The processes described herein are useful for depositing Si-containing films on a variety of substrates, including but not limited to substrates having mixed surface morphologies. In a preferred embodiment, a mixed-morphology Si-containing film is deposited onto the mixed substrate. The morphologies of the mixed-morphology film depend on the deposition temperature, pressure, reactant partial pressure(s) and reactant flow rates and the surface morphologies of the underlying substrate. Using cyclohexasilane, silicon-containing materials capable of forming single crystal films tend to form over properly prepared single crystal surfaces, whereas non-single crystal films tend to form over non-single crystalline surfaces. Epitaxial film formation is favored for silicon-containing materials capable of forming pseudomorphic structures when the underlying single crystal surface has been properly treated, e.g., by ex-situ wet etching of any oxide layers followed by in situ cleaning and/or hydrogen bake steps, and when the growth conditions support such film growth. Such treatment methods are known to those skilled in the art, see Peter Van Zant, “Microchip Fabrication,” 4^{th} Ed., McGraw Hill, New York, (2000), pp. 385. Polycrystalline and amorphous film formation is favored over amorphous and polycrystalline surfaces and over single crystal surfaces that have not been treated to enable epitaxial film growth. Amorphous film formation is favored over amorphous and polycrystalline substrate surfaces at low temperatures, while polycrystalline films tend to form over amorphous and polycrystalline surfaces at relatively high deposition temperatures.

Cyclohexasilane is preferably delivered to the mixed substrate surface for a period of time at a sufficient temperature for decomposition to initiate and at a delivery rate that is effective to form a Si-containing film having the desired thickness. Film thickness over a particular surface can range from about 10 Å to about 10 microns or even more, depending on the application. Preferably, the thickness of the Si-containing film over any particular surface is in the range of about 50 Å to about 5,000 Å, more preferably about 250 Å to about 2,500 Å.

For a mixed substrate comprising a first surface having a first surface morphology and a second surface having a second surface morphology, the Si-containing film deposited onto this mixed substrate preferably has a thickness T₁ over the first surface and a thickness T₂ over the second surface such that T₁:T₂ is in the range of about 10:1 to about 1:10, more preferably about 5:1 to about 1:5, even more preferably about 2:1 to about 1:2, and most preferably about 1.3:1 to about 1:1.3.

In a preferred embodiment, cyclohexasilane is used in a method for making a base structure for a bipolar transistor. The method for making the base structure comprises providing a substrate surface that comprises an active area and an insulator and supplying cyclohexasilane to the substrate surface under conditions effective to deposit a silicon-containing film onto the substrate over both the active area and the insulator.

In a preferred embodiment, the Si-containing film is deposited onto the mixed substrate in the form of a SiGe-containing film, preferably a SiGe or a SiGeC film, comprising from about 0.1 atomic % to about 80 atomic % germanium, preferably about 1 atomic % to about 60 atomic %. The SiGe-containing film is preferably deposited by simultaneously introducing a germanium source and cyclohexasilane to the chamber, more preferably by using a mixture of cyclohexasilane and a germanium source. The SiGe-containing film may be deposited onto a buffer layer as described above, preferably onto a silicon or doped silicon buffer layer, or directly onto the mixed substrate. More preferably, the germanium source is germane or digermane. The relative proportions of elements in the film, e.g., silicon, germanium, carbon, dopants, etc., are preferably controlled by varying the feed gas composition as discussed above. The germanium concentration may be constant through the thickness of the film or a graded film can be produced by varying the concentration of the germanium source in the feed gas during the deposition.

A preferred gas mixture for the deposition of SiGe comprises a hydrogen carrier gas, germane or digermane as the germanium source, and cyclohexasilane. The weight ratio of cyclohexasilane to germanium source in the feed gas is preferably in the range of about 10:90 to about 99:1, more preferably about 20:80 to about 95:5. To achieve preferred high rate deposition as described above, the germanium source is preferably delivered to the mixed substrate at a delivery rate of at least about 0.001 milligrams per minute per square centimeter of the mixed substrate surface, more preferably at least about 0.003 milligrams per minute per square centimeter of the mixed substrate surface. The delivery rate of the germanium source is preferably adjusted in concert with the delivery rate of cyclohexasilane to achieve the desired deposition rate and film composition. Preferably, the delivery rate of the germanium source is varied to produce a graded germanium concentration SiGe or SiGeC film.

Preferably, the surface morphology and composition of at least one surface of the underlying mixed substrate is effective to allow strained heteroepitaxial growth of SiGe films thereon. A deposited epitaxial layer is “strained” when it is constrained to have a lattice structure in at least two dimensions that is the same as that of the underlying single crystal substrate, but different from its inherent lattice constant. Lattice strain is present because the atoms depart from the positions that they would normally occupy in the lattice structure of the free-standing, bulk material when the film deposits in such a way that its lattice structure matches that of the underlying single crystal substrate. As discussed in greater detail below the present invention discloses methods of creating high levels of strain through achieving high levels of substitutional carbon.

Cyclohexasilane deposition conditions are thus preferably created by supplying sufficient energy to initiate the decomposition of cyclohexasilane and thus enable the resulting silicon products to deposit at a rate that is controlled primarily by the rate at which it is delivered to the substrate surface, more preferably by heating the substrate as described below. A preferred deposition method involves establishing cyclohexasilane decomposition and deposition conditions in a suitable chamber in the presence of cyclohexasilane and depositing a Si-containing film onto a substrate contained within the chamber. Alternatively, decomposition of cyclohexasilane may be initiated prior to the chamber by way of decomposition techniques such as, but not limited to, thermal, photolysis, radiation, ion bombardment, plasma, etc.

Various materials can be deposited in the usual fashion over the Si-containing materials described herein, including metals, dielectric materials, semiconductors, and doped semiconductors. Si-containing materials may also be subjected to other semiconductor manufacturing processes such as annealing, etching, ion implantation, polishing, etc.

Another preferred embodiment provides a method for making a diffusion source or diffusion layer. A diffusion source is a layer that acts as a source of one or more dopant elements. Such diffusion layers are typically deposited in close proximity to a region where the dopant is desired, then heated to drive the dopant from the diffusion layer to the desired destination. However, there are limitations on the use of such diffusion sources. For example, the deposition and drive steps are time-consuming, and the heating involved in these steps may exceed thermal budgets. Other doping methods such as ion implantation can be used, but shallow implantation is difficult to achieve by ion implantation.

Thus, there is a problem in making shallow doped regions such as shallow source-drain junctions. To minimize the impact on thermal budgets, attempts have been made to deposit thin diffusion sources in order to reduce the length of the diffusion pathway. However, such attempts using silane as the silicon source have been unsatisfactory because the deposition temperature for silane is high and because thickness non-uniformities in the diffusion layer resulted in corresponding dopant non-uniformities after the drive step.

It has now been discovered that thin, uniform Si-containing diffusion sources can be made using cyclohexasilane as the silicon source. These diffusion sources are preferably made by introducing cyclohexasilane and a dopant precursor to a chamber and depositing a highly doped Si-containing film by thermal CVD onto a substrate, in close proximity to the ultimate destination for the dopant. The amount of dopant precursor introduced to the chamber can vary over a broad range, depending on the ultimate application, but is preferably effective to provide a dopant concentration in the resulting diffusion source in the range of from about 1×10¹⁶ to about 1×10²² atoms/cm³. The ratio of dopant precursor to cyclohexasilane introduced to the chamber can range from about 0.00001% to 150%, preferably about 0.001% to about 75%, by weight based on total weight of cyclohexasilane and dopant precursor.

Diffusion layer deposition temperatures can be in the range of from about 400° C. to about 650° C., but are preferably in the range of about 450° C. to about 600° C. Lower deposition temperatures tend to have a smaller impact on thermal budgets and provide smoother, more continuous films, but higher temperatures tend to provide faster deposition. The thickness of the diffusion source is preferably in the range of about 25 Å to about 150 Å, more preferably about 50 Å to about 100 Å. The diffusion source is preferably a continuous Si-containing film having a substantially uniform thickness, more preferably having a thickness non-uniformity of about 10% or less, and a substantially uniform distribution of dopant(s).

The Si-containing films described herein are also useful as anti-reflective coatings. Photolithographic processes using intense sources of electromagnetic radiation are typically employed to pattern substrates in semiconductor manufacturing. Anti-reflective coatings are frequently applied to surfaces in order to reduce the amount of reflected radiation. The coating is usually designed so that its anti-reflective properties are maximized for the type of incident radiation by adjusting the thickness of the coating to be some multiple of the wavelength of the radiation. It is generally desirable for the multiple to be as small as possible in order to avoid secondary optical effects, but it is generally more difficult to prepare such thin, optical-quality films. In addition, as device dimensions have gotten smaller, the wavelength of incident radiation used for photolithography has also become shorter, with a commensurate decrease in the desired thickness for the anti-reflective coating.

A preferred embodiment provides anti-reflective coatings useful in semiconductor manufacturing. Preferred antireflective coatings comprise a Si-containing film as described herein that has a substantially uniform thickness, more preferably a thickness non-uniformity of about 10% or less, so that the antireflective properties are substantially constant across the surface of the substrate. The thickness of the anti-reflective coating is preferably selected to be effective to suppress reflection of at least part of the incident radiation, more preferably about 75% or less of the incident radiation is reflected. Typical thicknesses are lower multiples of the wavelength of the incident radiation, preferably about 100 Å to about 4000 Å, more preferably about 300 Å to about 1000 Å. The Si-containing film preferably comprises elemental nitrogen, oxygen and/or carbon, and is more preferably selected from the group consisting of Si—N, Si—O—N, and Si—C—N. Preferred anti-reflective coatings are preferably deposited using cyclohexasilane and, optionally, an oxygen, nitrogen and/or carbon precursor, using the deposition techniques taught elsewhere herein. Preferred oxygen precursors include diatomic oxygen and ozone; preferred nitrogen precursors include hydrazine, atomic nitrogen, hydrogen cyanide, and ammonia; and preferred carbon precursors include carbon dioxide, carbon monoxide, hydrogen cyanide, alkyl silanes and silylated alkanes. Such Si—N, Si—O—N, and Si—C—N films are also useful for other purposes, preferably for thin etch stops.

An apparatus is provided for depositing a Si-containing material, such as but not limited to, cyclohexasilane, trisilane, tetrasilane, disilane, pentasilane on a surface. A schematic diagram illustrating a preferred apparatus is shown in FIG. 1. This apparatus 100 comprises a carrier gas source 102, a temperature controlled bubbler 112 containing liquid cyclohexasilane 106, and a gas line 103 operatively connecting the gas source 102 to the bubbler 112. A CVD chamber 120, equipped with an exhaust line 130, is operatively connected to the bubbler 112 by a feed line 115. The flow of cyclohexasilane, entrained in the carrier gas, that is vaporized cyclohexasilane 107, from the bubbler 112 to the CVD chamber 120, is preferably aided by a temperature regulation source (not shown) operatively disposed in proximity to the bubbler. The temperature regulation source maintains the cyclohexasilane 106 at a temperature in the range of about 10° C. to about 70° C., preferably about 20° C. to about 52° C., to thereby control the vaporization rate of the cyclohexasilane. Preferably, the CVD chamber 120 is a single-wafer, horizontal gas flow reactor. Preferably, the apparatus is also comprised of a manifold (not shown) operatively connected to the feed line 115 to control the passage of the cyclohexasilane 106 from the bubbler 112 to the CVD chamber 120, desirably in a manner to allow separate tuning of the gas flow uniformity over the substrate(s) housed in the chamber 120. Preferably, the feed line 115 is maintained at a temperature in the range of about 35° C. to about 70° C., preferably about 40° C. to about 52° C., to prevent condensation of the vaporized cyclohexasilane 107.

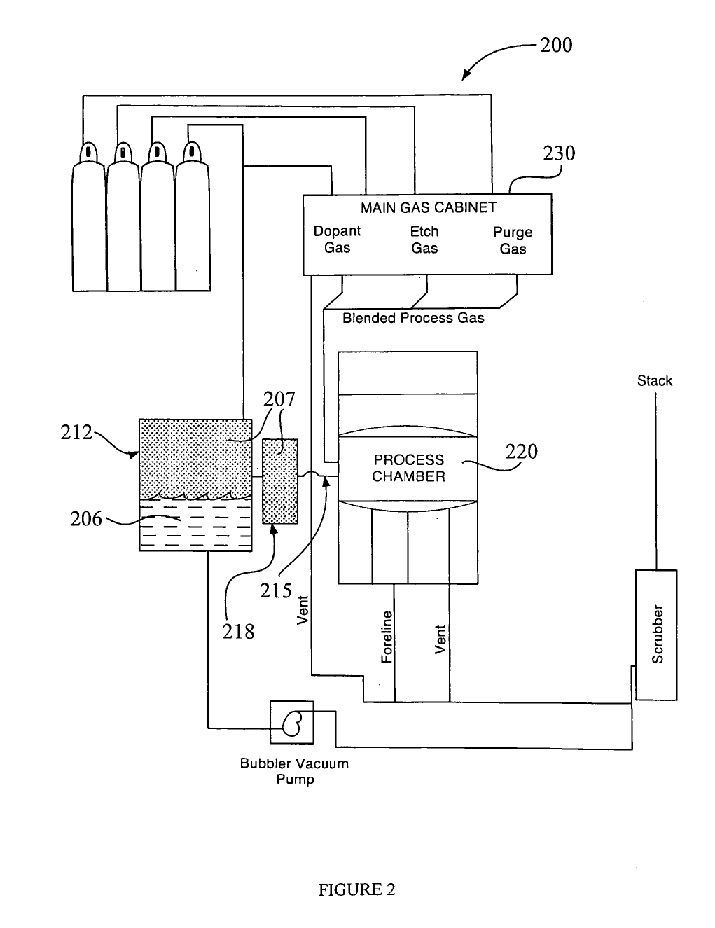

Alternatively, the apparatus described above in FIG. 1 can be modified according to FIG. 2 to incorporate a decomposition chamber 218 in feed line 215. Vaporized cyclohexasilane 207 enters decomposition chamber 218 and decomposition is initiated by way of thermal, photolysis, radiation, ion bombardment, plasma, etc., Such decomposition methods are known to those skilled in the art.

The yield of a semiconductor device manufacturing process that utilizes silane can be improved by replacing the silane with cyclohexasilane, as described herein. Although the replacement may improve yields in a variety of processes, it has particular utility when the process involves depositing a Si-containing film having an average thickness of about 2000 Å or less, and becomes increasingly preferred as film thickness is decreased. Thus, the replacement is useful for depositing films having a thickness of about 300 Å or less, even more useful for depositing films having a thickness of about 150 Å or less, and especially useful when for depositing films having a thickness of about 100 Å or less. Likewise, the replacement is particularly useful for improving yields when the surface area of the substrate is about 300 cm² or greater; and even more so when the surface area is about 700 cm² or greater.

Since the value of individual semiconductor devices is often quite high, even small increases in yield can result in significant cost savings for the manufacturer. Preferably, the replacement of silane with cyclohexasilane improves device yield by about 2% or more, more preferably about 5% or more, calculated as [cyclohexasilane device yield-silane device yield]/silane device yield, and multiplying by 100 to express the result as a percentage.

A preferred replacement method involves modifying a CVD process to take advantage of the ability to deposit cyclohexasilane at a lower temperature, e.g., using the temperature parameters discussed above for the thermal CVD of cyclohexasilane. For example, where the semiconductor device manufacturing process comprises thermal CVD of silane at a temperature Tₛ, the replacement of silane with cyclohexasilane preferably further involves reducing the deposition temperature to Tₜ, where Tₛ>Tₜ. Such temperature reductions advantageously conserve thermal budgets, and are preferably about 10% or greater, more preferably about 20% or greater, calculated as (Tₛ−Tₜ)/Tₛ, and multiplying by 100 to express the result in percentage terms. Preferably, Tₜ is in the range of about 450° C. to about 600° C., more preferably in the range of about 450° C. to about 525° C. Preferably, the process of introducing silane to the chamber is also modified when replacing the silane with cyclohexasilane to take into account the liquid nature of cyclohexasilane at room temperature as discussed above, e.g., by using a bubbler, heated gas lines, etc.

The present invention further provides a process for selectively and epitaxially depositing silicon and silicon-containing materials while accomplishing in situ substitutional doping of Si-containing materials. In addition, such improved methods disclosed herein are capable of achieving commercially significant levels of substitutional doping without unduly sacrificing deposition and/or growth speed, selectivity, and/or the quality (e.g., crystal quality) of the deposited materials. Furthermore, the process is versatile enough to form silicon-containing materials with varied elemental concentrations while having a fast deposition and/or growth rate and maintaining a process temperature in the range of about 250° C.-550° C., and preferably about 500° C.-525° C. while maintaining a pressure in the range of about 10 mTorr-200 Torr and preferably 10 mTorr-50 Torr and more preferably 10 mTorr-10 Torr. Finally, in the event the process requires multiple cycles as a result of etching there is no need to vary the temperature, that is, the etching step takes place at the same temperature as the deposition and/or growth step.

There are a number of deposition and/or growth parameters, as discussed in detail below, that are critical to selectively and epitaxially depositing silicon and silicon-containing materials while accomplishing in situ substitutional doping of Si-containing materials. It has been discovered that two critical parameters that allow one to accomplish the teachings of the present invention are the use higher order slimes including straight and isomeric forms, such as, but not limited to cyclohexasilane (n-cyclohexasilane, iso-cyclohexasilane and cyclo-cyclohexasilane) in combination with a low pressure chemical vapor deposition and/or growth system (as shown if FIGS. 1 and 2) which has been modified in accordance with the present invention to incorporate the use of a high speed pump.

The use of higher order silanes, such as, but not limited to cyclohexasilane, enables higher deposition and/or growth rate at lower temperature and for silicon-containing films incorporating carbon, higher incorporation of substitutional carbon atoms than the use of mono-silane as a silicon source gas. Higher silanes, such as cyclohexasilane, while easier to deposit at lower temperatures, thereby providing greater selectivity by enabling amorphous growth versus poly crystalline material. Higher silanes have traditionally been difficult to employ in epitaxy processes as they are prone to polymerization, thus forming higher chain polymers (gas phase nucleation) which deposit in the form of particles. These particles cause defects in the Si material and can disrupt epitaxy, resulting in possible transition to amorphous or polysilicon layers depending on the temperature. Lowering the deposition and/or growth temperature reduces the potential for gas phase nucleation. Unfortunately, however, as the deposition and/or growth temperature is lowered the partial pressure of oxygen, an impurity present in the epitaxy process, increases resulting in the interstitial incorporation of oxygen into the Si material. By extrapolating the work of Lander, et al., JAP, v 33(6): 2089-2092 (1962) at a deposition and/or growth temperature of 550° C. the partial pressure where oxygen is no longer stable on a clean surface is 10⁻¹⁶ Torr. Deposition and/or growth methods have now been developed for higher silanes, such as cyclohexasilane, that are much less sensitive to gas phase nucleation phenomena and that are useful for making a variety of substitutionally doped single crystalline Si-containing materials.

Surprisingly, it has been found that epitaxial silicon films may be formed by exposing a substrate contained within a chamber to a relatively high carrier gas flow rate in combination with a relatively low flow rate of cyclohexasilane by utilizing a reduced pressure CVD system having a high speed pump, at a temperature of less than about 550° C. and a pressure in the range of about 10 mTorr-200 Torr, preferably 10 mTorr-50 Torr and more preferably 10 mTorr-10 Torr. The high speed pump is capable of flowing a carrier gas into said chamber at concentrations so high that any contaminants, such as but not limited to oxygen, water, carbon monoxide, carbon dioxide, siloxanes, disiloxanes, and higher siloxanes present are diluted out.

Furthermore, the crystalline Si may be in situ doped to contain relatively high levels of substitutional carbon by carrying out the deposition and/or growth at a relatively high flow rate using cyclohexasilane as a silicon source and a carbon-containing gas as a carbon source under these modified CVD conditions. The deposition and/or growth of a single crystalline silicon film onto the substrate takes place at a temperature of less than about 550° C. and a pressure in the range of about 10 mTorr-200 Torr, preferably 10 mTorr-50 Torr and more preferably 10 mTorr-10 Torr, the single crystalline silicon film comprises about 1.8 atomic % to about 3.0 atomic % substitutional carbon, as determined by x-ray diffraction. The deposition and/or growth of carbon-doped layers in accordance with this invention can be conducted with or without an etchant gas, selectively or non-selectively, as described in greater detail below. In the event an etchant gas is employed there is the added benefit that the pressure and temperature do not need to be cycled depending upon whether the cycle is a deposition and/or growth or etching cycle.

As discussed above, various deposition and/or growth parameters have been found to affect the incorporation of substitutional carbon into Si-containing films, including: the ratio of cyclohexasilane to other silicon sources the ratio of carbon source flow rate to cyclohexasilane flow rate; the carrier gas flow rate; the deposition and/or growth pressure; and the deposition and/or growth temperature. It has been found that certain combinations of these parameters are particularly advantageous for achieving relatively high levels of substitutional carbon incorporation into Si-containing films. In particular, the following combinations are preferred: a relatively high carrier gas flow rate (e.g., a relatively low ratio of cyclohexasilane flow rate to hydrogen carrier gas flow rate) in combination with at least one of the following: a relatively low cyclohexasilane flow rate (e.g., about 50 mg/min to about 200 mg/min) a relatively low deposition and/or growth pressure (e.g., preferably in the range of from about 10 millitorr to about ten Ton and more preferably at a pressure of less than 1 Torr; and a relatively low deposition and/or growth temperature (e.g., preferably in the range of from about 250° C. to about 550° C., more preferably in the range of from about 500° C. to about 525° C.).

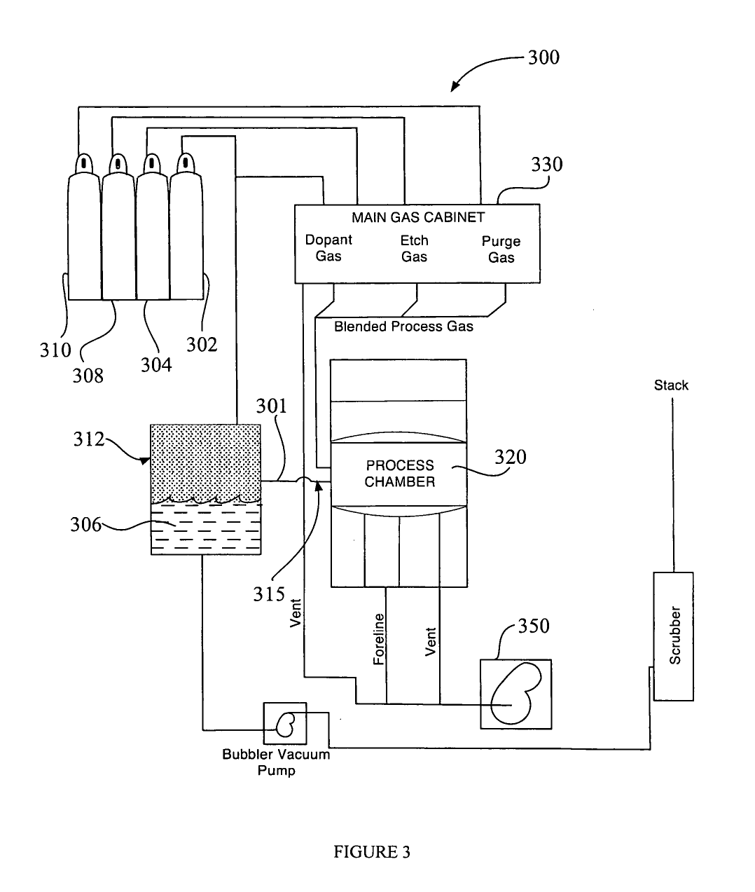

The amount of carbon substitutionally doped into a Si-containing material may be determined by measuring the perpendicular lattice spacing of the doped Si-containing material by x-ray diffraction. See, e.g., Judy L. Hoyt, “Substitutional Carbon Incorporation and Electronic Characterization of Si_{1-y}C_{y}/Si and Si_{1-x-y}GeₓC_{y}/Si Heterojunctions,” Chapter 3 in “Silicon-Germanium Carbon Alloy,” Taylor and Francis, N.Y., pp. 59-89, 2002. As illustrated in FIG. 3.10 at page 73 of the aforementioned article by Hoyt, the total carbon content in the doped silicon may be determined by SIMS, and the non-substitutional carbon content may be determined by subtracting the substitutional carbon content from the total carbon content. The amount of other elements substitutionally doped into other Si-containing materials may be determined in a similar manner.

Various embodiments provide methods for depositing carbon-doped Si-containing materials (such as carbon-doped single crystalline Si) using cyclohexasilane, a carbon source and, optionally, source(s) of other elements such as electrical active dopant(s). Under the modified chemical vapor deposition and/or growth conditions taught herein and described in further detail below, the delivery of decomposed cyclohexasilane and a carbon source to the surface of a substrate preferably results in the formation of an epitaxial carbon-doped Si-containing film on the surface of the substrate. In certain selective deposition and/or growths an etchant gas may be delivered to the substrate in conjunction with decomposed cyclohexasilane and carbon source, and the Si-containing film is deposited selectively over single crystal substrates or single crystal regions of mixed substrates. Methods employing relatively high deposition and/or growth rates are preferred, and in preferred embodiments such methods have been found to result in the deposition and/or growth of in situ doped crystalline Si-containing materials containing relatively high levels of substitutional carbon.

One or more embodiments of the invention generally provide processes to selectively and epitaxially deposit silicon-containing materials on monocrystalline surfaces of a substrate during fabrication of electronic devices. A substrate containing a monocrystalline surface (e.g., silicon or silicon germanium) and at least a secondary surface, such as an amorphous surface and/or a polycrystalline surface (e.g., oxide or nitride), is exposed to an epitaxial process to form an epitaxial layer on the monocrystalline surface while forming limited or no polycrystalline layer on the secondary surfaces. The epitaxial process typically includes repeating a cycle of a deposition and/or growth process and an etching process until the desired thickness of an epitaxial layer is grown. Exemplary alternating deposition and etch processes are disclosed in U.S. Pat. No. 7,312,128 the entire content of which is incorporated herein by reference.

In one or more embodiments, the deposition process includes exposing the substrate surface to a deposition gas containing at least cyclohexasilane and a carrier gas, wherein the carrier has a flow rate from 0-20,000 and preferably from 2,000 to 10,000 and more preferably from 100 to 2000 times greater than the flow rate of cyclohexasilane. The deposition gas may also include a germanium source and/or carbon source, as well as a dopant source. In particular embodiments, the deposition gas contains a sufficient amount of an n-type dopant precursor that results in the in the epitaxial film containing at least about 1×10²⁰ atoms/cm³ of an n-type dopant. In specific embodiments, the final epitaxial film contains at least about 2×10²⁰ atoms/cm³ of an n-type dopant, and more specifically, at least about 5×10²⁰ atoms/cm³ of an n-type dopant. As used herein, these levels of dopant concentration will be referred to as heavily doped with an n-type dopant. Examples of suitable n-type dopants include P, As and Sb. During the deposition process, an epitaxial layer is formed on the monocrystalline surface of the substrate, while a polycrystalline/amorphous layer is formed on secondary surfaces, such as dielectric, amorphous and/or polycrystalline surfaces, which will be collectively referred to as “secondary surfaces”. Subsequently, the substrate is exposed to an etching gas. Typically, the etching gas includes a carrier gas and an etchant, such as chlorine gas or hydrogen chloride. The etching gas removes silicon-containing materials deposited during the deposition process. During the etching process, the polycrystalline/amorphous layer is removed at a faster rate than the epitaxial layer. Therefore, the net result of the deposition and etching processes forms epitaxially grown silicon-containing material on monocrystalline surfaces while minimizing growth, if any, of polycrystalline/amorphous silicon-containing material on the secondary surfaces. A cycle of the deposition and etching processes may be repeated as needed to obtain the desired thickness of silicon-containing materials. The silicon-containing materials which can be deposited by embodiments of the invention include silicon, silicon germanium, silicon carbon, silicon germanium carbon, and variants thereof, including dopants.

Depending on the depth of the recess desired depositing and etching will occur for 30-50 cycles. In general, deposition processes may be conducted at lower temperatures than etching reactions, since etchants often need a high temperature to be activated. However, cyclohexasilane, due to the fact it can be deposited amorphously, allows for the etching process to be maintained at temperatures consistent with the deposition temperature thereby minimizing the effort to regulate and adjust the reaction temperatures throughout the deposition process.

Another preferred embodiment provides a method for performing blanket or nonselective epitaxy with alternating steps of deposition and etch results in improved crystallinity of epitaxial films grown using cyclohexasilane. An exemplary process includes loading a substrate into a process chamber and adjusting the conditions within the process chamber to a desired temperature and pressure. Then, a deposition process is initiated to form an epitaxial layer on a monocrystalline surface of the substrate at a rate of approximately 2-4 nm per minute. The deposition process is then terminated.

The substrates may be unpatterned or patterned. Patterned substrates are substrates that include electronic features formed into or onto the substrate surface. The patterned substrate usually contains monocrystalline surfaces and at least one secondary or feature surface that is non-monocrystalline, such as a dielectric, polycrystalline or amorphous surfaces. Monocrystalline surfaces include the bare crystalline substrate or a deposited single crystal layer usually made from a material such as silicon, silicon germanium or silicon carbon. Polycrystalline or amorphous surfaces may include dielectric materials, such as polysilicon, photoresist materials, oxides or nitrides, specifically silicon oxide or silicon nitride, as well as amorphous silicon surfaces or combinations thereof.

After loading a substrate into the process chamber, the conditions in the process chamber are adjusted to a predetermined temperature and pressure. The temperature is tailored to the particular conducted process. Generally, the process chamber is maintained at a temperature below about 550° C. during deposition and etching. The process chamber is usually maintained at a pressure in the range of about 10 mTorr-200 Torr, preferably 10 mTorr-50 Torr and more preferably 10 mTorr-10 Torr during deposition. The pressure may fluctuate during and between process steps, but is generally maintained constant.

During the deposition process the substrate is exposed to a deposition gas to form an epitaxial layer. The substrate is exposed to the deposition gas for a period of time of about 0.5 seconds to about 30 seconds, for example, from about 1 second to about 20 seconds, and more specifically from about 5 seconds to about 10 seconds. In a specific embodiment, the deposition step lasts for about 10 to 11 seconds. The specific exposure time of the deposition process is determined in relation to the exposure time during a subsequent etching process, as well as particular precursors and temperature used in the process. Generally, the substrate is exposed to the deposition gas long enough to form a maximized thickness of an epitaxial layer.

In one or more embodiments, the deposition gas contains at least cyclohexasilane and a carrier gas, and may contain at least one secondary elemental source, such as a carbon source or precursor and/or a germanium source or precursor. Also, the deposition gas may further include a dopant compound to provide a source of a dopant, such as boron, arsenic, phosphorus, gallium and/or aluminum. In an alternative embodiment, the deposition gas may include at least one etchant.

Cyclohexasilane as introduced to said chamber typically has a purity level in the range of approximately 95% to approximately 99.9% and having oxygenated impurities less than 2000 ppm and preferably having oxygenated impurities less than 2 ppm and more preferably having oxygenated impurities less than 500 ppb.

Cyclohexasilane is usually provided into the process chamber at a rate in a range from about 5 sccm to about 500 sccm, preferably from about 10 sccm to about 300 sccm, and more preferably from about 50 sccm to about 200 sccm, for example, about 100 sccm. In a specific embodiment, cyclohexasilane is flowed at about 60 sccm. Silicon sources useful in the deposition gas to deposit silicon-containing compounds include but are not limited to cyclohexasilane, halogenated cyclohexasilanes and organocyclohexasilanes. Halogenated silanes include compounds with the empirical formula X′_{y}Si₄H_{(10-y)}, where X′=F, Cl, Br or I. Organosilanes include compounds with the empirical formula R_{y}Si₄H_{(10-y),} where R=methyl, ethyl, propyl or butyl. Organosilane compounds have been found to be advantageous silicon sources as well as carbon sources in embodiments which incorporate carbon in the deposited silicon-containing compound.

Cyclohexasilane is usually provided into the process chamber along with a carrier gas. The carrier gas has a flow rate from about 1 slm (standard liters per minute) to about 50 slm, at a pressure of less than 100 Torr. For example, from about 12 slm to about 45 slm, and more specifically from about 20 slm to about 40 slm, for example, about 34 slm at a pressure of about less than 100 Torr. Carrier gases may include helium, nitrogen (N₂), hydrogen (H₂), argon, and combinations thereof. A carrier gas may be selected based on the precursor(s) used and/or the process temperature during the epitaxial process. Usually the carrier gas is the same throughout for each of the deposition and etching steps. However, some embodiments may use different carrier gases in particular steps. Typically, hydrogen is utilized as a carrier gas in embodiments featuring low temperature (e.g., less than 550° C.) processes.

The deposition gas used also contains at least one secondary elemental source, such as a carbon source and/or a germanium source. A carbon source may be added during deposition to the process chamber with the silicon source and carrier gas to form a silicon-containing compound, such as a silicon carbon material. A carbon source, i.e. 100%, is usually provided into the process chamber at a rate in the range from about 0.1 sccm to about 40 sccm, for eₓample, from about 3 sccm to about 25 sccm, and more specifically, from about 5 sccm to about 25 sccm, for example, about 10 sccm.

The carbon sources as introduced to said chamber typically has a purity level in the range of approximately 97% to approximately 99.9% and having oxygenated impurities less than 100 ppm and preferably having oxygenated impurities less than 10 ppm and more preferably having oxygenated impurities less than 500 ppb.

The deposition gas used during deposition may further include at least one dopant compound to provide a source of elemental dopant, such as boron, arsenic, phosphorus, gallium or aluminum. Dopants provide the deposited silicon-containing compounds with various conductive characteristics, such as directional electron flow in a controlled and desired pathway required by the electronic device. Films of the silicon-containing compounds are doped with particular dopants to achieve the desired conductive characteristic. In one example, the silicon-containing compound is doped n-type, such as with phosphorus, antimony and/or arsenic to a concentration in the range from about 10²⁰ atoms/cm³ to about 10²¹ atoms/cm³.

A dopant source is usually provided into the process chamber during deposition in the range from about 0.1 sccm to about 20 sccm, for example, from about 0.5 sccm to about 10 sccm, and more specifically from about 1 sccm to about 5 sccm, for example, about 3 sccm. Dopants may also include arsine (AsH₃), phosphine (PH₃) and alkylphosphines, such as with the empirical formula RₓPH₍₃₋ₓ₎, where R=methyl, ethyl, propyl or butyl and x=1, 2 or 3. Alkylphosphines include trimethylphosphine ((CH₃)₃P), dimethylphosphine ((CH₃)₂PH), triethylphosphine ((CH₃CH₂)₃P) and diethylphosphine ((CH₃CH₂)₂PH). Aluminum and gallium dopant sources may include alkylated and/or halogenated derivates, such as described with the empirical formula RₓMX₍₃₋ₓ₎, where M=Al or Ga, R=methyl, ethyl, propyl or butyl, X=Cl or F and x=0, 1, 2 or 3. Examples of aluminum and gallium dopant sources include trimethylaluminum (Me₃Al), triethylaluminum (Et₃Al), dimethylaluminumchloride (Me₂AlCl), aluminum chloride (AlCl₃), trimethylgallium (Me₃Ga), triethylgallium (Et₃Ga), dimethylgalliumchloride (Me₂GaCl) and gallium chloride (GaCl₃).

According to one or more embodiments, after the deposition process is terminated, the process chamber may be flushed with a purge gas or the carrier gas and/or the process chamber may be evacuated with a vacuum pump. The purging and/or evacuating processes remove excess deposition gas, reaction by-products and other contaminants. In an exemplary embodiment, the process chamber may be purged for about 10 seconds by flowing a carrier gas at about 5 slm. A cycle of deposition and etch may be repeated for numerous cycles.

In another aspect of the present invention, a blanket or non-selective deposition is performed at low temperatures, for example, below about 550° C. and lower, using a silicon source, preferably cyclohexasilane. This assists in amorphous growth (rather than polycrystalline) on dielectric surfaces such as oxide and nitride during the deposition step (nonselective deposition), which facilitates removal of the layer on dielectric surfaces by a subsequent etch step and minimizes damage on single crystalline layer grown on the crystalline substrate.

A typical selective epitaxy process involves a deposition reaction and an etch reaction. During the deposition process, the epitaxial layer is formed on a monocrystalline surface while a polycrystalline layer is deposited on at least a second layer, such as an existing polycrystalline layer and/or an amorphous layer. The deposition and etch reactions occur simultaneously with relatively different reaction rates to an epitaxial layer and to a polycrystalline layer. However, the deposited polycrystalline layer is generally etched at a faster rate than the epitaxial layer. Therefore, by changing the concentration of an etchant gas, the net selective process results in deposition of epitaxy material and limited, or no, deposition of polycrystalline material. For example, a selective epitaxy process may result in the formation of an epilayer of silicon-containing material on a monocrystalline silicon surface while no deposition is left on the spacer.

Selective epitaxial deposition of silicon-containing materials has become a useful technique during formation of elevated source/drain and source/drain extension features, for example, during the formation of silicon-containing MOSFET (metal oxide semiconductor field effect transistor) devices. Source/drain extension features are manufactured by etching a silicon surface to make a recessed source/drain feature and subsequently filling the etched surface with a selectively grown epilayers, such as a silicon germanium (SiGe) material. Selective epitaxy permits near complete dopant activation with in situ doping, so that the post annealing process is omitted. Therefore, junction depth can be defined accurately by silicon etching and selective epitaxy. On the other hand, the ultra shallow source/drain junction inevitably results in increased series resistance. Also, junction consumption during silicide formation increases the series resistance even further. In order to compensate for junction consumption, an elevated source/drain is epitaxially and selectively grown on the junction. Typically, the elevated source/drain layer is undoped silicon.

Embodiments of the present invention provide selective epitaxy processes for silicon-containing films, for example, Si:C films with high substitutional carbon concentration (greater than 1.8%), which can be used for forming tensile stressed channel of N-type Metal Oxide Semiconductor Field Effect Transistor (MOSFET) structure when epitaxial films are grown on recessed source/drain of a transistor. In general, it is difficult to achieve high substitutional carbon concentration (greater than 1.8%) in Si:C epitaxy. However, cyclohexasilane enables high growth rates at very low temperatures.

According to one or more embodiments, the methods follow a sequential order, however, the process is not limited to the exact steps described herein. For example, other process steps can be inserted between steps as long as the order of process sequence is maintained. The individual steps of an epitaxial deposition will now be described according to one or more embodiments.

MOSFET devices formed by processes described herein may contain a pMOS component or an nMOS component. The pMOS component, with a p-type channel, has holes that are responsible for channel conduction, while the nMOS component, with a n-type channel, has electrons that are responsible channel conduction. Therefore, for example, a silicon-containing material such as SiGe may be deposited in a recessed area to form a pMOS component. In another example, a silicon-containing film such as SiC may be deposited in a recessed area to form a nMOS component. SiGe is used for pMOS application for several reasons.

Further, SiGe grown epitaxially on the top of silicon has compressive stress inside the film because the lattice constant of SiGe is larger than that of silicon. The compressive stress is transferred in the lateral dimension to create compressive strain in the pMOS channel and to increase mobility of the holes. For nMOS application, SiC can be used in the recessed areas to create tensile stress in the channel, since the lattice constant of SiC is smaller than that of silicon. The tensile stress is transferred into the channel and increases the electron mobility. Therefore, in one embodiment, a first silicon-containing layer is formed with a first lattice strain value and a second silicon-containing layer is formed with a second lattice strain value.

To achieve enhanced electron mobility in the channel of nMOS transistors having a recessed source/drain using carbon-doped silicon epitaxy, it is desirable to selectively form the carbon-doped silicon epitaxial layer on the source/drain either through selective deposition or by post-deposition processing. Furthermore, it is desirable for the carbon-doped silicon epitaxial layer to contain substitutional C atoms to induce tensile strain in the channel. Higher channel tensile strain can be achieved with increased substitutional C content in a carbon-doped silicon source and drain. Achieving a 1.5% substitutional C is equivalent to approximately a 0.5% channel strain, whereas a 2% substitutional C is equivalent to approximately a 0.8% channel strain, whereas a 2.5% substitutional C is equivalent to approximately a 1.0% channel strain and a 3% substitutional C is equivalent to approximately a 1.2% channel strain.

Methods for formation of epitaxial layers containing n-doped silicon are known in the art and are not described in detail herein. Specific embodiments pertain to the formation and treatment of epitaxial layers in semiconductor devices, for example, MOSFET devices. In specific embodiments, the formation of the n-doped epitaxial layer involves exposing a substrate in a process chamber to deposition gases including a silicon source, a carbon source and an n-dopant source at a first temperature and pressure and then exposing the substrate to an etchant without varying the temperature or the pressure.

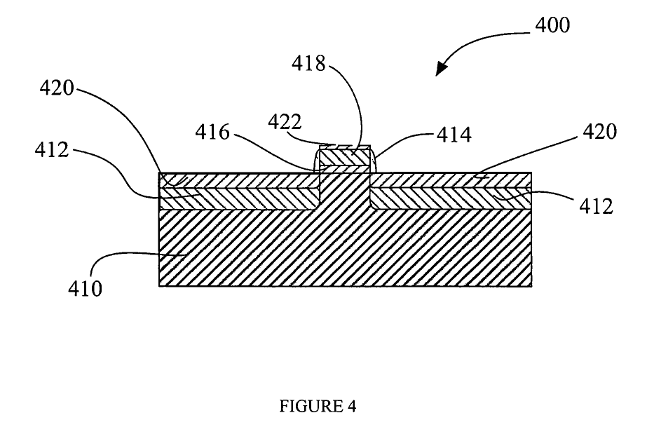

In one example, as depicted in FIG. 4, a source/drain extension is formed within a MOSFET device 400 wherein the silicon-containing layers are epitaxially and selectively deposited on the surface of the substrate 410. A source/drain region 412 is formed by implanting ions into the surface of a substrate 410. The segments of source/drain region 412 are bridged by the gate 418 formed on gate oxide layer 416 and spacer 414.

In another example, silicon-containing epitaxial layer 420 and polycrystalline layer 422 are SiC-containing layers with a carbon concentration in a range of at least about 1.8 atomic % substitutional carbon to at least about 3.0 atomic % substitutional carbon, as determined by x-ray diffraction.

In another example, silicon-containing epitaxial layer 420 and polycrystalline layer 422 are SiGe-containing layers with a germanium concentration in a range from about 1 at % to about 50 at %, preferably about 24 at % or less. Multiple SiGe-containing layers containing varying amounts of silicon and germanium may be stacked to form silicon-containing epitaxial layer 240 with a graded elemental concentration. For example, a first SiGe-layer may be deposited with a germanium concentration in a range from about 15 at % to about 25 at % and a second SiGe-layer may be deposited with a germanium concentration in a range from about 25 at % to about 35 at %.

FIG. 3 illustrates a preferred reactor system 300 employing a carrier gas 302 (helium in the illustrated embodiment), a carbon source 304 (methylsilane in the illustrated embodiment), a silicon source 306 (cyclohexasilane in the illustrated embodiment) and an etching gas 308. Reactor system 300 utilized by the present invention comprises a Centura® RP-CVD (Reduced Pressure-Vacuum Chemical Vapor Deposition) manufactured by Applied Materials and modified according to the present invention by adding a high flow pump 350 as discussed further below.

The gases introduced into the reactor system 300 are highly purified by a gas purifier (not shown) before being introduced into reaction chamber 320. Therefore, it is necessary to provide the gas purifier such that the gas is introduced into the reaction chamber 320 after having been purified highly. Thereby, an impurity of oxygen, water, siloxanes, carbon monoxide (CO), carbon dioxide (CO₂) or the like included in the gas, is minimized. Some of the carrier gas 302 flow is shunted to a vaporizer in the form of a bubbler 312, from which carrier gas 302 carries vaporized cyclohexasilane 307 at a ratio of approximately 0.005, thereby forming a saturated process gas.

The carrier gas 302 merges with the other reactants at the main gas cabinet 330, upstream of the injection manifold (not shown) for deposition chamber 320. A source of etchant gas 308 is also optionally provided for selective deposition processes.

As illustrated, the reactor system 300 also includes a high speed pump 350. It has been discovered that this high speed pump 350 is essential to the present invention as it allows main carrier gas 302 flowing to the chamber to flow at a much higher rate than that of cyclohexasilane saturated vapor 307, that is in the range of 0-20,000 and preferably from 2,000 to 10,000 and more preferably from 100 to 2000 times greater than the flow rate of the cyclohexasilane saturated vapor 307. These high flow rates at the low deposition temperatures, that is, less than 550° C. which are disclosed herein, minimize the incorporation of oxygen containing impurities such as but not limited to oxygen, water, carbon monoxide, carbon dioxide, siloxanes, disiloxanes, higher siloxanes into the Si film. It is preferable that the interstitial oxygen content should be 1E18 atom/cm³ or lower and preferably less than 2E17 atom/cm³. Interfacial oxygen content should be below SIMS detectable limits (dose at interface) with a background of 5E17 atom/cm³. Interstitial carbon content should be 5E17 atom/cm³ or lower. Interfacial carbon should be below SIMS detectable limits with a minimum background of 5E17 atom/cm³ or lower. This requirement is accomplished as a result of the high speed pump 350 as carrier gas 302 at pressures in the range of about 10 mTorr-200 Torr, preferably 10 mTorr-50 Torr and more preferably 10 mTorr-10 Torr has a flow rate of up to 50 slm which is approximately two hundred times that of cyclohexasilane saturated vapor 307; consequently, impurities that may be present in reaction chamber 320 are literally diluted out.

A central controller (not shown), electrically connected to the various controllable components of reactor system 300. The controller is programmed to provide gas flows, temperatures, pressures, etc., to practice the deposition processes as described herein upon a substrate housed within reaction chamber 320. As will be appreciated by the skilled artisan, the controller typically includes a memory and a microprocessor, and may be programmed by software, hardwired or a combination of the two, and the functionality of the controller may be distributed among processors located in different physical locations. Accordingly, the controller can also represent a plurality of controllers distributed through reactor system 300.

In the illustrated embodiment, with the carbon source 304 in combination with cyclohexasilane saturated vapor 307, selective deposition of high substitutional carbon content Si:C can be achieved, as disclosed hereinabove. In another embodiment, the dopant hydride source 310 is preferably also provided to produce in situ doped semiconductor layers with enhanced conductivity. Preferably, for Si:C epitaxy, the dopant hydride is arsine or phosphine, and the layer is n-type doped. More preferably, for selective deposition embodiments, the diluent inert gas for the dopant hydride is also hydrogen gas. Thus, phosphine 310 and methylsilane 304 are preferably stored at their source containers in, e.g., hydrogen. Typical dopant hydride concentrations are 0.1% to 5% in hydrogen 302, more typically 0.5% to 1.0% in hydrogen for arsine and phosphine. Typical carbon source concentrations are 5% to 50% in hydrogen 302, more typically 10% to 30% in hydrogen. For example, experiments are being conducted with 20% methylsilane 304 in hydrogen 302.

Alternatively, the apparatus described above in FIG. 3 can be modified to incorporate a decomposition chamber (not shown) in feed line f. Vaporized cyclohexasilane 307 enters decomposition chamber and decomposition is initiated by way of thermal, photolysis, radiation, ion bombardment, plasma, etc., Such decomposition methods are known to those skilled in the art.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments. The order of description of the above method should not be considered limiting, and methods may use the described operations out of order or with omissions or additions.

The foregoing description is considered as illustrative only of the principles of the invention. Further, since numerous modifications and changes will readily occur to those skilled in the art, it is not desired to limit the invention to the exact construction and process as described above. Accordingly, all suitable modifications and equivalents may be resorted to falling within the scope of the invention as defined by the claims that follow. The words “comprise,” “comprising,” “include,” “including,” and “includes” when used in this specification and in the following claims are intended to specify the presence of stated features, integers, components, or steps, but they do not preclude the presence or addition of one or more other features, integers, components, steps, or groups thereof.

What is claimed is:

1. A method for depositing a thin film, comprising:
introducing a process gas comprising cyclohexasilane to a chamber, wherein said chamber contains a substrate;
establishing cyclohexasilane chemical vapor deposition conditions in said chamber;
initiating decomposition of said cyclohexasilane; and
depositing an epitaxial Si-containing film onto said substrate.

2. The method of claim 1, further comprising depositing an oxide layer directly onto said epitaxial Si-containing film.

3. The method of claim 1, wherein said process gas further comprises a dopant element selected from the group consisting of boron, arsenic, antimony, indium, and phosphorous.

4. The method of claim 1, wherein initiating decomposition of said cyclohexasilane occurs by heating said chamber to a temperature in the range of about 400° C. to about 750° C.

5. The method of claim 1, wherein initiating decomposition of said cyclohexasilane occurs prior to introducing said cyclohexasilane to said chamber.

6. The method of claim 1, wherein establishing cyclohexasilane deposition conditions comprises maintaining said chamber pressure between about 1 Torr and 100 Torr.

7. The method of claim 1, wherein said process gas further comprises a carrier gas.

8. The method of claim 7, wherein said carrier gas further comprises helium, hydrogen, nitrogen or argon.

9. The method of claim 7, wherein said carrier gas flow rate is about two hundred times greater than the flow rate of said cyclohexasilane.

10. The method of claim 1, wherein said process gas further comprises a carbon source.

11. The method of claim 10, wherein said carbon source is selected from the group consisting of a silicon carbon source.

12. The method of claim 10, wherein said carbon source is selected from the group comprising a formula SiₓH_{y}(CH₃)_{z}, where x is an integer in the range of 1 to 6 and where y and z are each individually an integer in the range of 0 to 6.

13. The method of claim 11, wherein said silicon is selected from the group consisting of: tetramethyldisilane, and methylated cyclohexasilane.

14. The method of claim 10, wherein said carbon doped silicon epitaxial layer has a substitutional C value of between 1.8 and 3.0 atomic percent

15. A method for blanket depositing a silicon containing material on a substrate, comprising:
positioning a substrate containing a crystalline surface and at least one feature surface within a process chamber, wherein said feature surface comprises a material selected from the group consisting of an oxide material, a nitride material, poly silicon, photoresist or combinations thereof;
heating the substrate to a predetermined temperature of about 550° C. or less; and
exposing the substrate to a process gas containing cyclohexasilane to deposit a silicon-containing blanket layer across the crystalline surface and the feature surfaces wherein said process carrier gas flows at a rate of about 150 to 250 times greater than said cyclohexasilane.

16. The method of claim 15, wherein said process gas further contains a carbon source selected from the group comprising a formula SiₓH_{y}(CH₃)_{z}, where x is an integer in the range of 1 to 6 and where y and z are each individually an integer in the range of 0 to 6.

17. The method of claim 16, wherein said carbon source is selected from the group consisting of methylsilane, dodecalmethylcyclohexasilane or tetramethyldisilane.

18. The method of claim 15, wherein said carbon doped silicon epitaxial layer has a substitutional C value of between 1.8 and 3.0 atomic percent.

19. The method of claim 15, wherein establishing cyclohexasilane deposition conditions comprises maintaining said process chamber pressure between about 1 Torr and 100 Torr.

20. Apparatus for forming an epitaxial film on a substrate in a chemical vapor deposition system, comprising:
a decomposition chamber having an inlet and an outlet;
a deposition chamber having chamber dimensions and opposite ends operatively connected to said deposition chamber;
high-speed pump means connected to one of the ends of the chamber and operative to maintain the deposition pressure in the chamber at or below 200 Torr;
a gas inlet adjacent the other of the ends of the chamber for introducing gas into the chamber so that the gas flows generally in a direction from the gas inlet to the pump means;
substrate support means for supporting the substrate within the chamber; and
high speed pump evacuates a carrier gas out of said chamber at a speed sufficient to maintain the pressure less than 200 Torr.
